(19) United States
(12) Patent Application Publication
(10) Pub. No.: US 2011/0090143 A1
(43) Pub. Date: Apr. 21, 2011

(54) ELECTROPHORETIC DISPLAY DEVICE AND FABRICATION METHOD THEREOF

(76) Inventors: Seung-Han PAEK, Bucheon (KR); Sang-Il Shin, Cheorwon-Gun (KR)

(21) Appl. No.: 12/906,636

(22) Filed: Oct. 18, 2010

(30) Foreign Application Priority Data
Oct. 20, 2009 (KR) 10-2009-0099894
Aug. 4, 2010 (KR) 10-2010-0075362

(51) Int. Cl. G09G 3/34; H01L 33/48

(52) U.S. Cl. 345/107; 438/28; 257/E33.056

(57) ABSTRACT

Disclosed is an electrophoretic display device and fabrication method capable of reducing fabricating costs and simplifying a fabrication process by forming an electrophoretic layer directly on a substrate having a thin film transistor or a substrate having a common electrode. The method including preparing a first and second substrates each having a display region and a non-display region, forming a thin film transistor on the first substrate, forming a passivation layer on the first substrate having the thin film transistor to be planarized, forming a pixel electrode on the passivation layer, forming an electrophoretic layer directly on the passivation layer and the pixel electrode, forming a common electrode on the second substrate, and bonding the first substrate and the second substrate to each other.

This application claims the benefit of Korean Patent Application Nos. 10-2009-0099894, filed Oct. 20, 2009 and 10-2010-0075362, filed on Aug. 4, 2010, which are hereby incorporated by reference as if fully set forth herein.

### BACKGROUND OF THE INVENTION

### Field of the Invention

The present invention relates to an electrophoretic display device and a fabrication method thereof, and particularly, to an electrophoretic display device, capable of reducing a fabricating cost and a fabrication time by forming an electrophoretic layer directly on a substrate having a thin film transistor or a substrate having a common electrode, and a fabrication method thereof.

In general, an electrophoretic display device is an image display device using a phenomenon that when a pair of electrodes, to which a voltage is applied, are put into a colloidal solution, particles move toward a particular polarity. The electrophoretic display device has several advantageous properties of wide viewing angle, high reflectivity and low power consumption without use of backlights, so it is spotlighted as an electronic device such as electric paper and the like.

The electrophoretic display device has a structure having an electrophoretic layer interposed between two substrates. One of the two substrates may be a transparent substrate and another one may be a TFT array substrate, which can selectively provide an electric field to electrophoretic particles. One or both of the two substrates may be configured as a transparent substrate.

FIG. 1 shows a structure of the related art electrophoretic display device 1. As shown in FIG. 1, the electrophoretic display device 1 includes an array substrate 100 and an upper substrate 110. The array substrate 100 includes a first substrate 20, a thin film transistor (TFT) formed on the first substrate 20, and a pixel electrode 18. The upper substrate 110 includes a transparent second substrate 40, a common electrode 42 formed on the second substrate 40, and an electrophoretic layer 60 on the common electrode 42. The array substrate 100 and the upper substrate 110 are bonded to each other by interposing the electrophoretic layer 60 therebetween. The electrophoretic layer 60 is attached onto the array substrate 100 by virtue of an adhesive layer 56.

Each TFT includes a gate electrode 11 formed on the first substrate 20, a gate insulation layer 22 formed all over the first substrate 20 having the gate electrode 11, a semiconductor layer 13 located on the gate insulation layer 22, and a source electrode 15 and a drain electrode 16 on the semiconductor layer 13. The source electrode 15 and the drain electrode 16 of the TFT are located on a passivation layer 24.

The pixel electrode 18 for applying a signal to the electrophoretic layer 60 is formed on the passivation layer 24. Here, the passivation layer 24 is provided with a contact hole 28 such that the pixel electrode 18 on the passivation layer 24 can be connected to the drain electrode 16 of the TFT through the contact hole 28.

Also, the common electrode 42 is formed on the second substrate 40, and the electrophoretic layer 60 is formed on the common electrode 42. Microcapsules 70 filled with white particles 74 and black particles 76 are distributed in the electrophoretic layer 60. If a signal is applied to the pixel electrode 18, an electric field is generated between the common electrode 42 and the pixel electrode 18, and the electric field allows movement of the white particles 72 and the black particles 76 within the microcapsules 70, thereby implementing an image.

For instance, if (−) voltage is applied to the pixel electrode 18, the common electrode 42 of the second substrate 40 relatively has (+) potential. Accordingly, the white particles 74, for example, having (+) charge move toward the first substrate 20 with the pixel electrode 18 thereon while the black particles 76 having (−) charge move toward the second substrate 40 with the common electrode 42 thereon. In this state, if light is input from the outside, namely, from the upper side of the second substrate 40, the input light is reflected by the black particles 76, accordingly the electrophoretic display device represents a black color.

On the other hand, if (+) voltage is applied to the pixel electrode 18, the common electrode 42 of the second substrate 40 relatively has (−) potential. Accordingly, the white particles 74, for example, having (+) charge move toward the second substrate 40 while the black particles 76 having (−) charge move toward the first substrate 20. In this state, if light is input from the outside, namely, from the upper side of the second substrate 40, the input light is reflected by the white particles 74, accordingly the electrophoretic display device implements a white color.

However, the electrophoretic display device 1 according to the related art has the following problems.

In the related art electrophoretic display device 1, the independently fabricated array and upper substrates 100 and 110 are bonded by the adhesive layer 56. That is, TFT and the pixel electrode 18 are formed on the first substrate 20 to fabricate the array substrate 100, and the common electrode 42 is formed on the transparent second substrate 40 and the electrophoretic layer 60 is attached onto the common electrode 42 to independently fabricate the upper substrate 110, thereafter, the array substrate 100 and the upper substrate 110 are bonded to each other, thereby creating the electrophoretic display device 1.

The first and second substrates 20 and 40 having fabricated through different processes are conveyed by means of a conveyer and bonded to each other through a bonding process. The adhesive layer 56 is further formed on one surface of the electrophoretic layer 60 formed on the upper substrate 110, and the adhesive layer 56 is protected by a protection film (not shown). Therefore, upon bonding the upper substrate 110 and the array substrate 100 to each other, the protection film is first peeled off to expose the adhesive layer 56, thus bonding the upper substrate 110 and the array substrate 100 to each other.

As such, in the method of fabricating the electrophoretic display device according to the related art, since the protection film is attached onto the electrophoretic layer 60 formed on the upper substrate 110, the bonding of the array substrate 100 and the upper substrate 110 is available after peeling off the protection film. During peel-off of the protection film, typically formed of a plastic film, from the electrophoretic layer 60, static electricity is generated, which causes charged particles of the electrophoretic layer 60 to be randomly arranged, thereby causing a defect of an initial image quality of the electrophoretic display device.

Furthermore, upon bonding the upper substrate 110 having the electrophoretic layer 60 to the array substrate 100, the array substrate 100 and the upper substrate 110 should be precisely aligned to urge electrophoretic particles exactly matched with unit pixels. Typically, an extremely complicated process is needed to bond the upper substrate 110, which has the electrophoretic layer 60 with microcapsules of about 100 micrometers in size, and the array substrate 100, which has unit pixels of about 100 micrometers in size, such that one unit pixel can match with one microcapsule, resulting in occurrence of misalignment.

### SUMMARY OF THE INVENTION

Therefore, in order to overcome those problems of the related art, an object of the present invention is to provide an electrophoretic display device, capable of reducing a fabricating cost and simplifying a fabrication process by forming an electrophoretic layer directly on a substrate having a thin film transistor or a substrate having a common electrode, and a fabrication method thereof.

To achieve these and other advantages and in accordance with the purpose of the present invention, as embodied and broadly described herein, there is provided a method for fabricating an electrophoretic display device including preparing a first substrate and a second substrate each having a display region and a non-display region, forming a thin film transistor on the first substrate, forming a passivation layer on the first substrate having the thin film transistor to be planarized, forming a pixel electrode on the passivation layer, forming an electrophoretic layer directly on the passivation layer and the pixel electrode, forming a common electrode on the second substrate, and bonding the first substrate and the second substrate to each other.

The forming of the electrophoretic layer may include depositing microcapsules directly on the passivation layer and the pixel electrode, each microcapsule containing a solvent as polymer binder, and electronic inks of charged white and black particles.

The forming of the electrophoretic layer may include forming partition walls on the passivation layer and the pixel electrode, filling the charged particles together with a dispersing agent (dispersive medium) in a room defined by the partition walls, and sealing the room.

Also, the forming of the electrophoretic layer may include forming partition walls on the passivation layer and the pixel electrode, forming a sealing layer on a room defined by the partition wall, the sealing layer having an injection hole, injecting the charged particles together with the dispersive medium in the room through the injection hole of the sealing layer, and sealing the injection hole.

In accordance with one embodiment, there is provided an electrophoretic display device including a first substrate and a second substrate each having a display region and a non-display region, a thin film transistor formed on the first substrate, a passivation layer and a pixel electrode formed on the first substrate having the thin film transistor, the pixel electrode formed on the passivation layer, a common electrode formed on the second substrate, partition walls formed directly on the common electrode and directly contactable with the passivation layer, and an electrophoretic layer filled in a room defined by the partition walls.

Since an electrophoretic layer can be formed by being coated directly on a substrate having a TFT, an adhesive layer for bonding the electrophoretic layer onto the array substrate or a protection film for protecting the adhesive layer may not be needed, thereby reducing a fabricating cost. Also, the electrophoretic layer can be formed in line with an array substrate fabrication line for forming a thin film transistor, resulting in simplification of a fabrication process.

Also, a protection film for protecting the electrophoretic layer may not be used at all, which allows solution of image quality degradation due to static electricity, which is generated upon peeling off the protection film. Also, the electrophoretic layer may be formed directly on the array substrate having the thin film transistor, thereby thoroughly solving image quality degradation due to misalignment, as compared to the related art, in which the electrophoretic layer is independently fabricated and then attached through an alignment process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a view of a related art electrophoretic display device;

FIGS. 2A to 2H are views sequentially showing a method of fabricating an electrophoretic display device in accordance with one exemplary embodiment;

FIGS. 3A and 3B are views respectively showing a method of forming an electrophoretic layer of the electrophoretic display device;

FIGS. 4A to 4E are views sequentially showing a method of fabricating an electrophoretic display device in accordance with a second exemplary embodiment;

FIGS. 5A to 5D are views sequentially showing a method of fabricating an electrophoretic display device in accordance with a third exemplary embodiment;

FIGS. 6A to 6D are views sequentially showing a method of fabricating an electrophoretic display device in accordance with a fourth exemplary embodiment; and

FIGS. 7A to 7D are views sequentially showing a method of fabricating an electrophoretic display device in accordance with a fifth exemplary embodiment.

### DETAILED DESCRIPTION OF THE INVENTION

Description will now be given in detail of an electrophoretic display device according to the exemplary embodiments, with reference to the accompanying drawings.

In accordance with the present disclosure, an electrophoretic layer may be formed directly on a first substrate having TFTs or a second substrate. That is, the electrophoretic layer may be formed during a TFT fabrication process or a common electrode forming process. Therefore, the electrophoretic layer can be formed by using fabrication equipment for an electrophoretic display device, such as equipment for fabricating the TFTs, thereby remarkably simplifying a fabrication process, as compared to the related art method of fabricating an electrophoretic display device, namely, bonding the second substrate and the first substrate after forming the electrophoretic layer on the second substrate through a independent process.

In general, in the related art fabrication process of the electrophoretic display device, an electrophoretic layer provided from a different factory, more particularly, from another supplier is conveyed to a manufactory for forming TFTs, and thereafter bonded to a first substrate, thereby delaying the fabrication process and making the fabrication process complicated. Furthermore, during the convey of the second substrate using a transportation, such as a vehicle, the second substrate may be confronted with damage.

On the other hand, in accordance with the present disclosure, since an electrophoretic layer can be formed either on a first substrate or on a second substrate by using fabricating equipment for an electrophoretic display device, such as existing fabricating equipment for TFTs or the like, it makes it possible to fast fabricate an electrophoretic display device. Also, the electrophoretic display device can be formed during a TFT process of the first substrate or a common electrode forming process of the second substrate, not through a independent process, thereby allowing an in-line formation of TFTs and common electrodes.

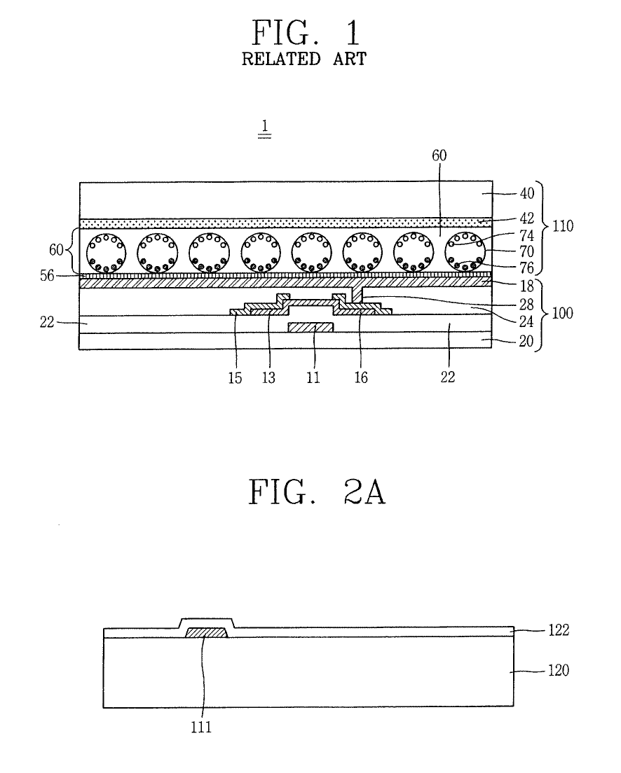

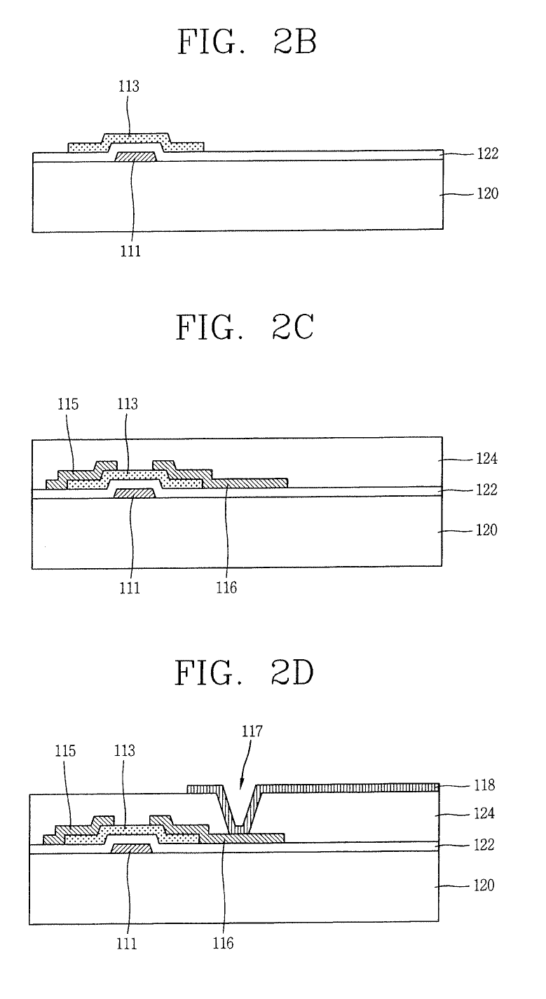

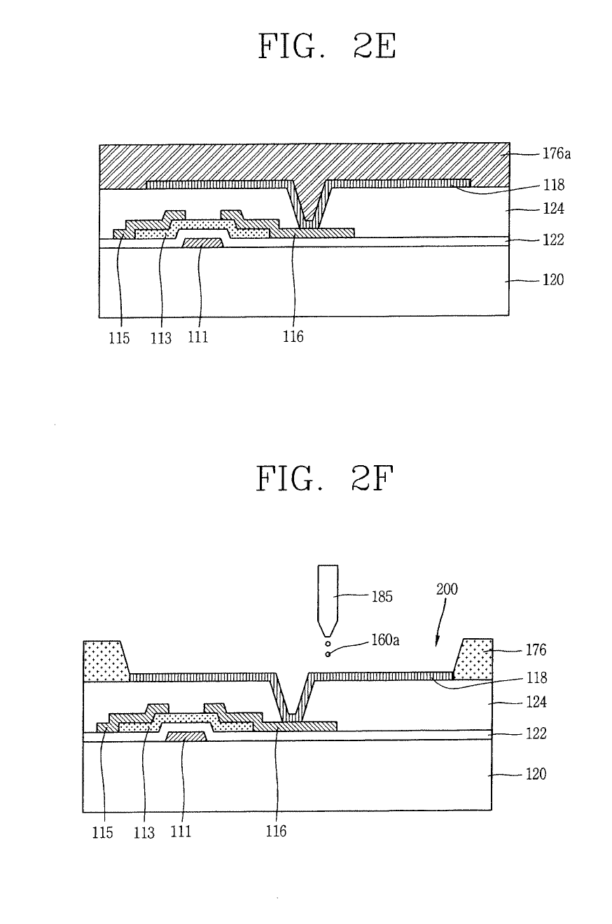

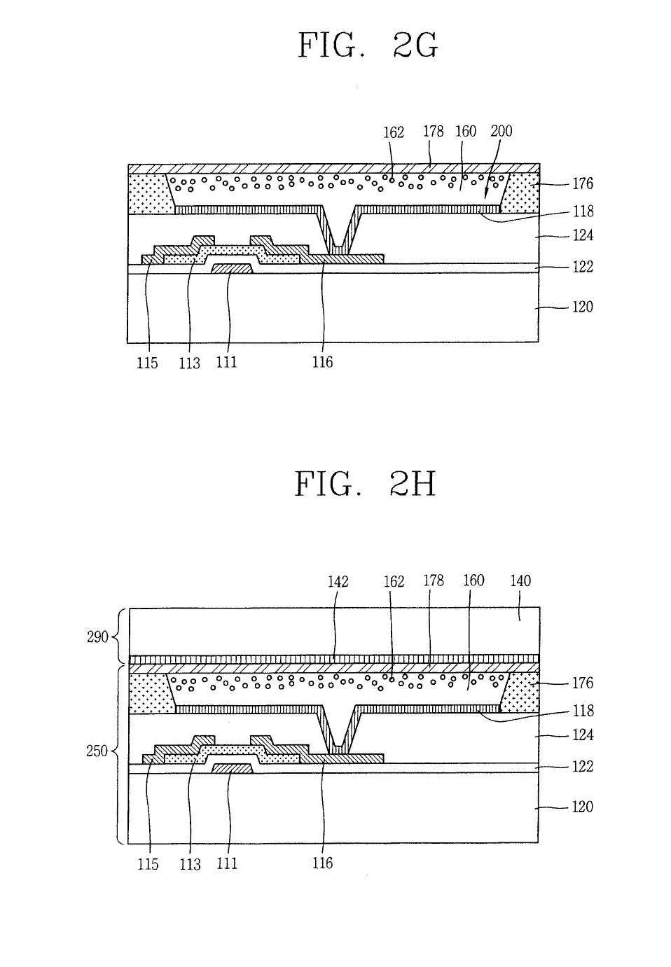

FIG. 2 shows a method of fabricating an electrophoretic display device in accordance with one exemplary embodiment.

First, as shown in FIG. 2A, an opaque metal with high conductivity, such as Cr, Mo, Ta, Cu, Ti, Al or Al alloy, are deposited on a first substrate 120 made of a transparent material, such as glass or plastic, through a sputtering process, and etched by a photolithography process, thereby forming a gate electrode 111. An inorganic insulating material, such as SiO₂ or SiNx, is deposited on the entire surface of the first substrate 120 having the gate electrode 111 thereon through a chemical vapor deposition (CVD), thereby forming a gate insulation layer 122.

Referring to FIG. 2B, a semiconductor material, such as amorphous silicon (a-Si), is deposited on the entire first substrate 120 through a CVD scheme to thereafter be etched, thereby forming a semiconductor layer 113. Although not shown, amorphous silicon doped or added with impurity is deposited on part of the semiconductor layer 113, thereby forming an ohmic contact layer, which allows an ohmic contact between the semiconductor layer 113 and source and drain electrodes which will be formed later.

Referring to FIG. 2C, an opaque metal having high conductivity, such as Cr, Mo, Ta, Cu, Ti, Al or Al alloy, is deposited on the first substrate 120 through a sputtering process and then etched out, thereby forming a source electrode 115 and a drain electrode 116 on the semiconductor layer 113, strictly speaking, on the ohmic contact layer. An organic insulating material, such as benzocyclobutene (BCB) or photoacryl, is deposited all over the first substrate 120 having the source electrode 115 and the drain electrode 116, thereby forming a passivation layer 124. The passivation layer 124 mainly functions to planarize the surface of the first substrate 120 on which TFTs are formed, and additionally serves to protect the TFTs on the first substrate 120 from external environments.

Although not shown, the passivation layer 124 may be formed by a plurality of layers. For example, the passivation layer 124 may be implemented as a double layer including an organic insulation layer formed of an organic insulating material, such as BCB or photoacryl, and an inorganic insulation layer formed of an inorganic insulating material, such as SiO₂ or SiNx, or implemented as a triple layer of an inorganic insulation layer, an organic insulation layer and an inorganic insulation layer. The formation of the organic insulation layer may allow the surface of the passivation layer 124 to be planar, and the employment of the inorganic insulation layer may improve an interfacial property with the passivation layer 124.

Afterwards, referring to FIG. 2D, the passivation layer 124 on the drain electrode 116 of the TFT is etched out to form a contact hole 117. Afterwards, a transparent conductive material or a metal layer is deposited on the passivation layer 124 and then etched out so as to form a pixel electrode 118. Here, the pixel electrode 118 is electrically connected to the drain electrode 116 through the contact hole 117.

Referring to FIG. 2E, an insulating material, such as resin or the like, is deposited on the passivation layer 124 to form an insulation layer 176a. Afterwards, referring to FIG. 2F, the insulation layer 176a is patterned to form partition walls 176 on the first substrate 120. The partition wall 176 is formed in a lattice form on the passivation layer 124 and the pixel electrode 118 so as to form a space, namely, a room 200 to be filled with an electrophoretic material. The partition wall 176 may be formed to correspond to a unit pixel of the room 200. Afterwards, an electrophoretic material 160a, in which white particles and color particles are mixed in a dispersive medium, is dropped in the room 200 by use of an inkjet device 185.

The partition walls 176 may also be formed by depositing the insulation layer 176a, such as photosensitive resin or the like, on the passivation layer 124 and the pixel electrode 118 and etching the insulation layer 176a through a photolithography process using a photoresist. Alternatively, the partition walls 176 patterned may be printed on the passivation layer 124 and the pixel electrode 118 through a printing process. As another method, a mold having grooves corresponding to the partition walls 176 may be fabricated to transcribe an insulating material of the mold onto the first substrate 120, thereby forming the partition walls 176.

Substantially, the method of forming the partition walls 176 may not be limited to specific methods. Those aforesaid methods are merely illustrative for the sake of explanation, so, they should not be construed to limit the present disclosure. The partition walls 176 may also be formed by various methods which are already well known.

The electrophoretic material may be composed of white particles and color particles or white particles and black particles. Also, the electrophoretic material may contain the dispersive medium. Accordingly, white particles and color particles or white particles and black particles may move within the dispersive medium responsive to an electric field applied thereto. For a mono type electrophoretic display device, which merely represents black and white images, the electrophoretic material may only contain white particles and black particles. For an electrophoretic display device representing various colored images, the electrophoretic material may contain white particles and color particles.

Referring to FIG. 2G, as the electrophoretic material containing color particles is dropped into the room 200, an electrophoretic layer 160 with colors is formed on the first substrate 120. Hereinafter, the space defined by the partition walls 176 is indicated as the room 200, and a layer formed by filling the electrophoretic material in the room 200 is indicated as the electrophoretic layer 160. Here, in the electrophoretic layer 160, white particles 162 and color particles with a specific color are distributed in the dispersive medium, thus moving within the dispersive medium as an electric field is applied. Here, the electrophoretic material 160a may be filled in the room 200 by various methods. Those filling methods of the electrophoretic material will be described hereinafter.

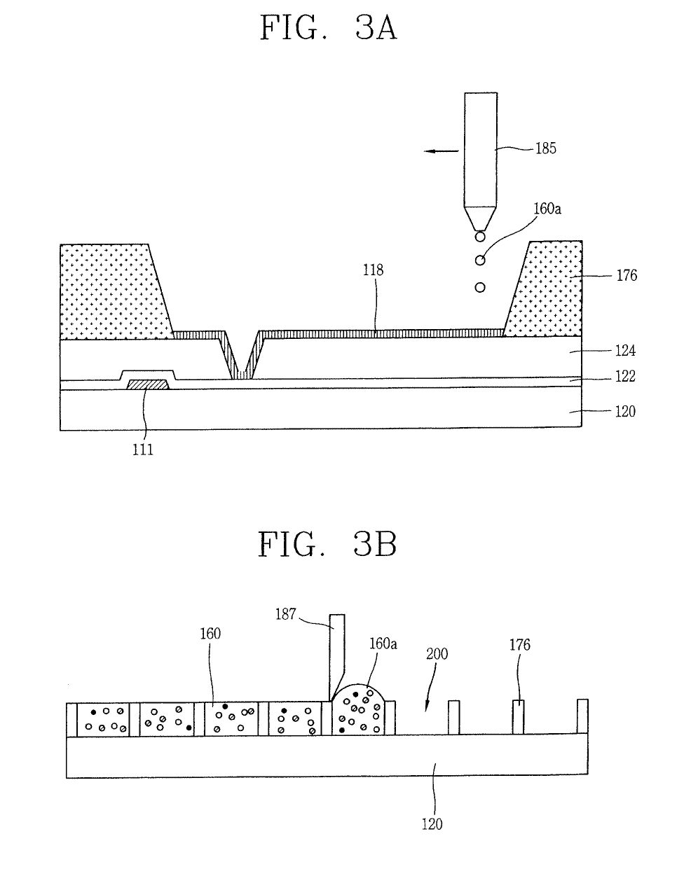

FIGS. 3A and 3B respectively show a method for forming the electrophoretic layer 160 by filling the electrophoretic material in the room 200 defined by the partition walls 176 formed on the first substrate 120.

A method shown in FIG. 3A is a method using an inkjet or a nozzle. Referring to FIG. 3A, after filling the electrophoretic material 160a in a syringe (or nozzle) 185, the syringe 185 is placed above the first substrate 120. As the syringe 185 moves above the first substrate 120 in a state where a pressure is applied to the syringe 185 by an external air supply device (not shown), the electrophoretic material 160a is dropped in the space between the partition walls 176, thereby forming the electrophoretic layer 160 on the first substrate 120.

Although not shown in detail, when the electrophoretic material 160a is filled in the room 200 defined by the partition walls 176, a syringe 185 containing color particles with a specific color is aligned above the corresponding pixel so as to inject the color particles into the room 200.

A method shown in FIG. 3B is a squeezing method. Referring to FIG. 3B, after depositing the electrophoretic material 160a on the first substrate 120 having the plurality of partition walls 176, a squeeze bar 187 is employed to squeeze the electrophoretic material 160a on the first substrate 120, such that the electrophoretic material 160a can be filled in the rooms 200 defined by the partition walls 176 by the pressure of the squeeze bar 187. The electrophoretic material 160a filled in each room 200 forms the electrophoretic layer 160.

Although not shown, for fabricating a color electrophoretic display device, upon filling the electrophoretic material 160a containing color particles with a specific color, for example, a red color, the room 200 to be filled with color particles with a green or blue color is shielded by a resist or the like. Hence, the red electrophoretic material 160a can be filled in the corresponding room 200 through the squeezing method. Green color particles and blue color particles may then be sequentially filled in corresponding rooms 200 through the same method, thereby fabricating the electrophoretic display device capable of representing colored images.

Here, the present disclosure may not be limited to the aforesaid methods or processes. Those methods merely illustrate examples of forming the electrophoretic layer 160 to be applicable in the present disclosure. For example, various processes of forming the electrophoretic layer 160, such as casting, bar-coating, screen printing, molding and the like, may be applicable.

Afterwards, a sealing layer 178 is formed on the electrophoretic layer 160 and the partition walls 176. The sealing layer 178 may be formed by coating photocurable resin or thermosetting resin on the electrophoretic layer 160 and the partition walls 176, followed by hardening. The sealing layer 178 may be formed for preventing the dispersive medium with low viscosity from overflowing to the exterior or into an adjacent room 200, due to running over the originally-filled room 200. Hence, the formation of the sealing layer 178 may depend on a material of the dispersive medium. For instance, if the dispersive medium of the electrophoretic layer 160, filled in the room 200, has high viscosity, and thus does not overflow into a neighboring room 200, the formation of the sealing layer 178 may not be needed.

Afterwards, referring to FIG. 2H, an array substrate 250 having the electrophoretic layer 160 is bonded to an upper substrate 290, which is fabricated independently from the array substrate and has the common electrode 142, thereby obtaining an electrophoretic display device. Here, the upper substrate 290 is a substrate obtained by forming the common electrode 142 as a transparent electrode on the transparent second substrate 140, so no unit pixel is defined thereon. Therefore, the bonding can be completed merely by stacking the upper substrate 290 on the array substrate 250, resulting in easily solving an alignment error.

The common electrode 142 is formed on the second substrate 140 made of a transparent material, such as glass or plastic. The common electrode 142 may be formed by depositing a transparent conductive material, such as ITO or IZO, on the second substrate 140.

Although not shown, as another method of fabricating a color electrophoretic display device, a color filter layer may further be formed on the second substrate 140. That is, the color filter layer may include red (R), green (G) and blue (B) sub-color filters. When the electrophoretic layer 160 merely contains white particles and black particles so as to merely implement a black-and-white screen, the color filter layer may be formed on another surface of the second substrate 140 having the common electrode 142 so as to render colors.

After a sealant or bonding agent is coated along an edge of the first substrate 120 or the second substrate 140, the first substrate 120 and the second substrate 140 are bonded in an aligned state therebetween, thereby fabricating the electrophoretic display device.

A structure of the thusly-fabricated electrophoretic display device will be described in detail with reference to FIG. 2H.

Referring to FIG. 2H, in the electrophoretic display device fabricated according to the aforesaid method, the partition walls 176 are formed directly on the array substrate 250. In detail, the partition walls 176 are formed by coming in contact directly with the passivation layer 124 and the pixel electrode 118 of the array substrate 250 and the dispersive medium and the electrophoretic particles are filled in the room 200 defined by the partition walls 176 such that the electrophoretic layer 160 containing the dispersive medium and the electrophoretic particles can come in contact directly with the pixel electrode 118 and the passivation layer 124. Hence, unlike the related art electrophoretic display device, a separate adhesive layer for attaching the electrophoretic layer 160 may not be needed between the electrophoretic layer 160 and the pixel electrode 118 and the passivation layer 124.

Alternatively, unlike the above structure of the electrophoretic display device, the partition walls 176 may be formed directly on the surface having the passivation layer 124 and the pixel electrode 118 thereon, in particular, not on the pixel electrode 118 but only on the passivation layer 124 between unit pixel electrodes 118.

An operation of the electrophoretic display device with the configuration will be described as follows.

If the electrophoretic material 160 is composed of white particles and black particles, since the white particles have positive or negative charge properties, when an external signal is applied to the pixel electrode 118 via the TFT formed on the first substrate 120, an electric field is generated between the pixel electrode 118 and the common electrode 142. The electric field makes charged particles, for example, the black or white particles, or charged color particles for a color electrophoretic display device, move within the dispersive medium.

For example, when the white particles have (+) charge, if (+) potential is applied to the pixel electrode 118 and (−) potential is relatively applied to the common electrode 142 on the second substrate 140, the white particles with (+) charge move towards the second substrate 140. Therefore, when light is input from the exterior, namely, from an upper side of the second substrate 140, the input light is reflected by the white particles, thereby implementing a white color on the electrophoretic display device.

On the other hand, when (−) potential is applied to the pixel electrode 118, if the common electrode 142 of the second substrate 140 has (+) potential, the white particles with (+) charge move towards the first substrate 120 and the black particles with (−) charge move towards the second substrate 140. Accordingly, when external light is input, the input light is rarely reflected, thereby implementing a black color.

For a color electrophoretic display device, unlike the mono type, if the electrophoretic material contains color particles other than black particles, charged R, G and B color particles or other color particles, such as cyan, magenta and yellow, move between the common electrode and the pixel electrode in response to a signal applied to the pixel electrode 118, thereby implementing colors.

If the electrophoretic material is in a form of a spherical capsule, which covers white particles, black particles and dispersive medium, since the white particles and the black particles distributed in the capsule have positive and negative charge properties (or negative and positive charge properties), respectively, when an external signal is applied to the pixel electrode 118, an electric field is generated between the pixel electrode 118 and the common electrode 142, accordingly, the white particles and the black particles are divided by the electric field in the capsule. For instance, if (−) voltage is applied to the pixel electrode 118, the common electrode 142 of the second substrate 140 has relatively (+) potential, such that the white particles with (+) charge move toward the first substrate 120 and the black particles with (−) charge move towards the second substrate 140. Under this state, if light is input from the exterior, namely, an upper side of the second substrate 140, a black color may be implemented on the electrophoretic display device.

As described, the electrophoretic layer 160 may directly be formed on the first substrate 120, so it can be formed through the existing TFT forming process line, e.g., a process line such as forming of an insulation layer or the like. Consequently, a process line therefor may not be needed independently, thereby further reducing a fabricating cost.

Also, since the electrophoretic display device can be configured such that the partition walls are formed on the array substrate with unit pixels to correspond to the respective unit pixels, the problem relating to misalignment can be fundamentally avoided, as compared to the related art technique in which the electrophoretic layer is formed on the upper substrate and accordingly bonding of the upper substrate and the lower substrate, e.g., the array substrate are performed with aligning the same with each other.

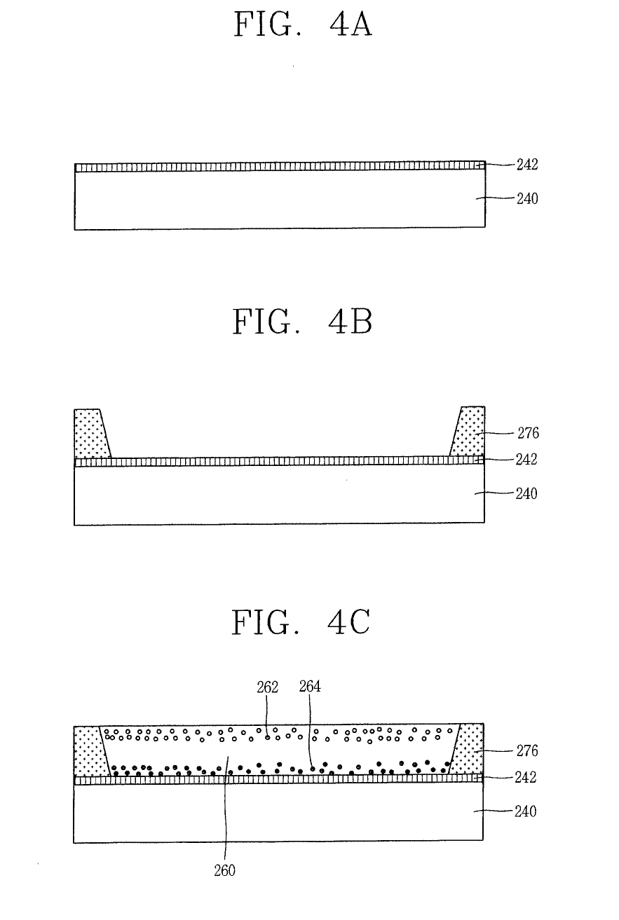

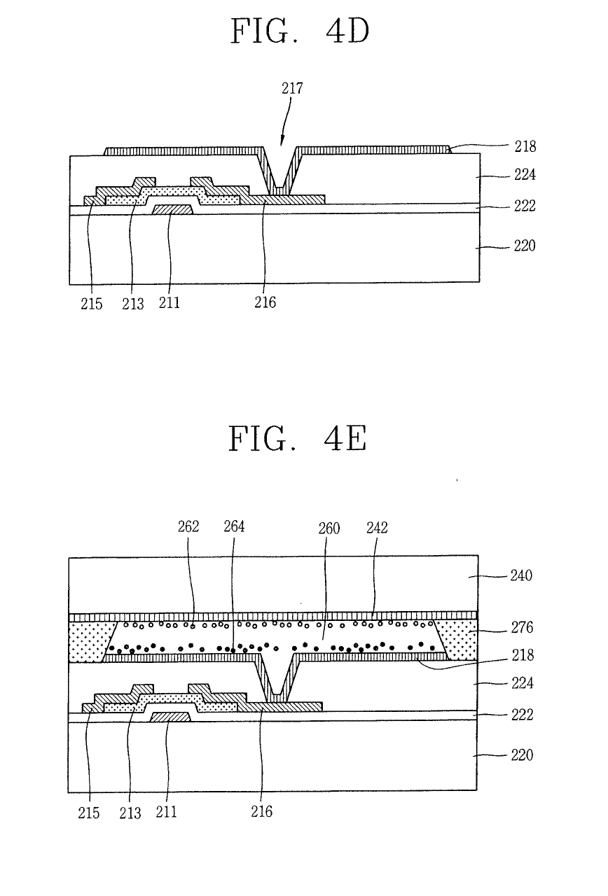

FIGS. 4A to 4E are views sequentially showing a method of fabricating an electrophoretic display device in accordance with a second exemplary embodiment, which shows that an electrophoretic layer is formed on an upper substrate having a common electrode.

First, referring to FIG. 4A, a transparent conductive material, such as ITO or IZO, is deposited on a second substrate 240 made of a transparent material, such as glass or plastic, to form a common electrode 242. Referring to FIG. 4B, partition walls 276 are formed on the second substrate 240 having the common electrode 242 thereon. The formation of the partition walls 276 may be achieved by one of those methods described in the first embodiment. For instance, the partition walls 276 may be formed by depositing an insulation layer, such as resin or the like, on the common electrode 242, follows by a photolithography process or a molding process.

Referring to FIG. 4C, an electrophoretic material is filled in a space defined by the partition walls 276 to form an electrophoretic layer 260. Here, the electrophoretic material may be composed of a dispersive medium including solvent or liquid polymers, and electrophoretic particles 262 dispersed in the dispersive medium. For a mono type, the electrophoretic particles 262 may contain white particles and black particles, and for a color type, the electrophoretic particles 262 may contain color particles. Here, the white particles and the black particles may respectively have negative charge properties and positive charge properties, or respectively have positive charge properties and negative charge properties. Also, if color particles are contained, the color particles may also have positive or negative charge properties. The electrophoretic layer 260 may be formed by various methods, such as screen printing, dropping and the like.

Referring to FIG. 4D, an array substrate is formed. That is, a TFT, which comprises a gate electrode 211, a gate insulation layer 222, a source electrode 215 and a drain electrode 216, is formed on a first substrate 220, and a passivation layer 224 is formed on the TFT. Afterwards, a pixel electrode 218 electrically connected to the drain electrode 216 via a contact hole 217 is formed on the passivation layer 224. Here, the TFT may be formed through the processes shown in FIGS. 2A to 2C.

Referring to FIG. 4E, the first substrate 220 having the TFT and the second substrate 240 having the electrophoretic layer 260 are bonded to each other, thereby achieving an electrophoretic display device.

In accordance with this embodiment, the electrophoretic layer 260 is injected in the room 200 defined by the partition walls 276a without forming a sealing layer for sealing the room 200 on the second substrate 240 having the electrophoretic layer 260. Then, a independently fabricated array substrate is bonded directly to the second substrate 240 having the electrophoretic layer 260. Therefore, in accordance with the second embodiment, during the bonding process, preferably, the second substrate 240 having the electrophoretic layer 260 may be placed at a lower side and the array substrate having the pixel electrode 218 may be placed at an upper side so as to be bonded to each other.

Although not shown, if the electrophoretic layer 260 contains white particles and black particles, a color filter layer may further be formed on the second substrate 240 so as to implement colors.

The bonding of the first and second substrates 220 and 240 may be realized by coating a sealant or a bonding agent along an edge of the first or second substrate 220 or 240, i.e., on a non-display region and then applying a pressure to the first and second substrates 220 and 240 in an aligned state of both of them.

Alternatively, the bonding of the first and second substrate 220 and 240 may be achieved as follows. That is, when forming the partition walls 276 on the second substrate 240, the partition wall 276 formed on an edge of a display region of the second substrate 240 may be formed to have a wider upper end in width, as compared to the partition wall formed within the display region, and thereby the sealant or bonding agent may be coated on the upper ends of the partition walls 276 formed on the edge of the display region of the second substrate 240, thereby bonding the first and second substrate 220 and 240 to each other.

The first embodiment exemplarily illustrates that the electrophoretic layer is formed directly on the first substrate having the TFT and thereafter the first substrate is bonded to the second substrate to fabricate the electrophoretic display device, whereas the second embodiment exemplarily illustrates that the electrophoretic layer is formed on the second substrate having the common electrode and thereafter the second substrate is bonded to the first substrate to fabricate the electrophoretic display device.

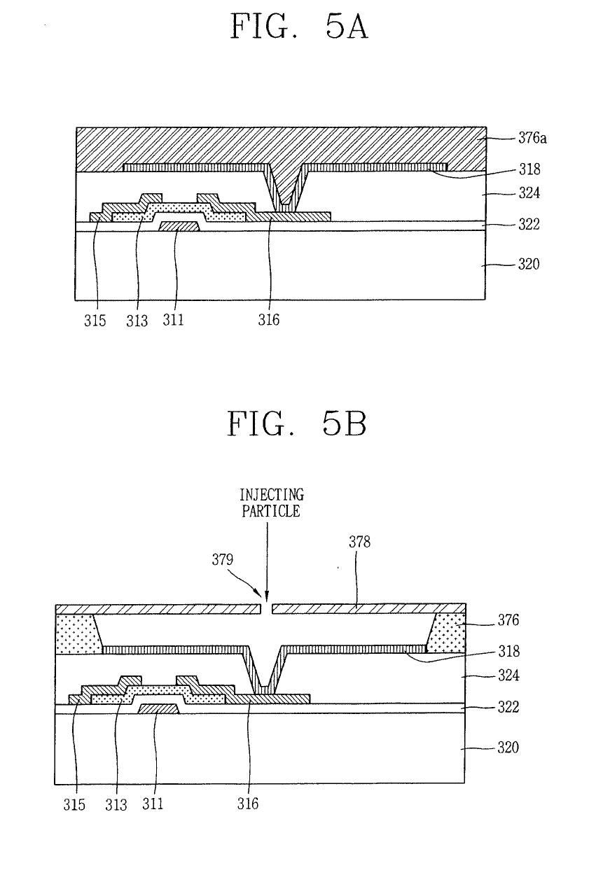

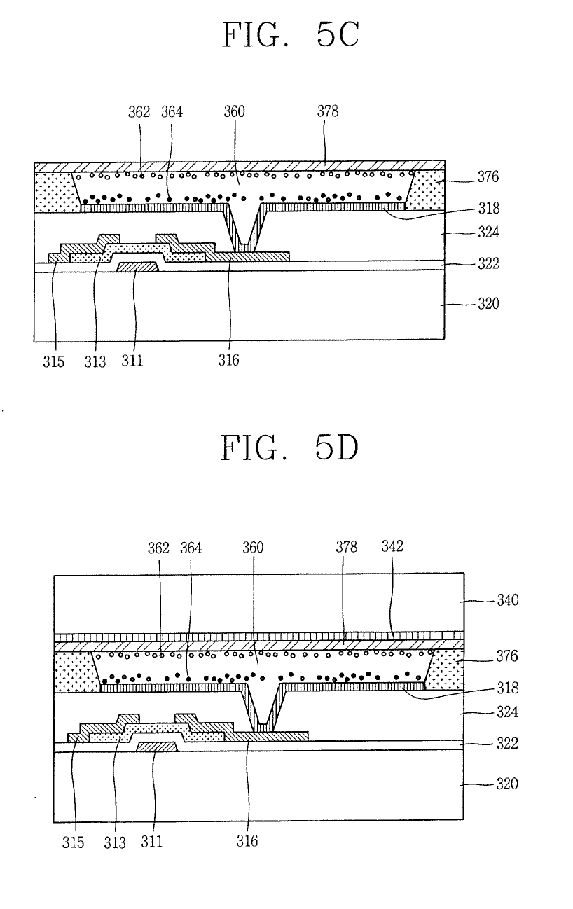

FIGS. 5A to 5D are views sequentially showing a method of fabricating an electrophoretic display device in accordance with a third exemplary embodiment. The third embodiment may be characterized in that an injection hole is further formed at a sealing layer for sealing a room 200 defined by partition walls so as to inject an electrophoretic material through the injection hole.

Referring to FIG. 5A, a TFT comprising a gate electrode 311, a gate insulation layer 322, a semiconductor layer 313, a source electrode 315 and a drain electrode 316 is formed on the first substrate 320, and a passivation layer 324 is formed all over the first substrate 320 to cover the TFT. The TFT may be formed through the processes shown in FIGS. 2A to 2C, and the passivation layer 324 may be formed by depositing an organic insulating material.

A pixel electrode 318 electrically connected to the drain electrode 316 of the TFT through a contact hole is formed on the passivation layer 324, and an insulation layer 376a is formed by coating an insulating material, such as resin or the like, on the first substrate 320 having the pixel electrode 318.

Referring to FIG. 5B, the insulating layer 376a is patterned to form partition walls 376 on the first substrate 320. Here, the partition walls 376 may be formed by depositing the insulating layer 376a such as resin or the like and then etching out the same through a photolithography process using a photoresist, or by printing patterned partition walls 376 by using a printing roll. Alternatively, the partition walls 376 may be formed by fabricating a mold having grooves corresponding to the partition walls 376 and transcribing an insulating material of the mold onto the first substrate 320.

Substantially, the method of forming the partition walls 376 may not be limited to specific methods. Those aforesaid methods are merely illustrative for the sake of explanation, so, they should not be construed to limit the present disclosure. The partition walls 376 may also be formed by various methods which are already well known.

Afterwards, a sealant or the like is coated and hardened on the partition walls 376 to form a sealing layer 378 having an injection hole 379. An electrophoretic material containing white particles 362 and color particles 364 are injected into a space defined by the partition walls 376 and the sealing layer 378 via the injection hole 379. Here, air is filled in the space and the injection of the white particles 362 and the color particles 364 may be realized by contacting a particle injector onto the injection hole 379 in a state where pressure within the space defined by the partition walls 376 and the sealing layer 378 is maintained lower than air pressure. Alternatively, the white particles 362 and the color particles 364 may be injected by the particle injector with pressure higher than air pressure in a state of matching pressure within the space defined by the partition walls 376 and the sealing layer 378 with the air pressure.

Afterwards, referring to FIG. 5C, the injection hole 379 is sealed after filling the white particles 362 and the color particles 364 with charges in the space defined by the partition walls 376, thereby forming an electrophoretic layer 360.

Referring to FIG. 5D, the first substrate 320 having the electrophoretic layer 360 is bonded to a second substrate 340 having a common electrode 342, thereby fabricating an electrophoretic display device.

In regard to the electrophoretic display device with the configuration, since the white particles 362 and the color particles 364 distributed in the electrophoretic layer 360 have positive charge properties and negative charge properties, respectively, when an external signal is applied to the pixel electrode 318 via the TFT formed on the first substrate 320, an electric field is generated between the pixel electrode 318 and the common electrode 342, accordingly, the white particles 362 and the color particles 364 are divided within the dispersive medium due to the electric field. For instance, when (−) voltage is applied to the pixel electrode 318, the common electrode 342 of the second substrate 340 relatively has (+) potential, such that the white particles 362 with (+) charge move towards the first substrate 320 and the color particles 364 with (−) charge move towards the second substrate 340. Under this state, when light is input from the exterior, i.e., from an upper side of the second substrate 340, the input light is reflected by the color particles 364, which allows colors to be rendered on the electrophoretic display device.

On the other hand, when (+) voltage is applied to the pixel electrode 318, the common electrode 342 of the second substrate 340 has (−) potential, such that the white particles 362 with (+) charge move towards the second substrate 340 and the color particles 364 with (−) charge move towards the first substrate 320.

Under this state, when light is input from the exterior, i.e., from an upper side of the second substrate 340, the input light is reflected by the white particles 362, thereby rendering a white color.

In the drawings, one pixel is shown, but the electrophoretic display device may substantially include pixels filled with R, G and B color particles arranged thereon, accordingly, colors corresponding to the respective pixels can be rendered, thereby enabling desired colors to be displayed.

Also, a white sub pixel, which does not have a color filter layer, may further be provided in each unit pixel for improvement of brightness of the electrophoretic display device. The electrophoretic display device is a reflective display. Hence, if the color filter layer is further formed on the electrophoretic layer, brightness may be drastically lowered. However, the white sub pixels can solve the problem of brightness degradation.

In the meantime, the electrophoretic display device with the configuration may not be used only as a display device for representing colors. If a color filter layer 346 is not formed on the second substrate 340, light reflected by the white particle 372 may render a white color, while light reflected by a black particle 374 may render a black color. Hence, the electrophoretic display device with the configuration may also be used as a black-and-white display device.

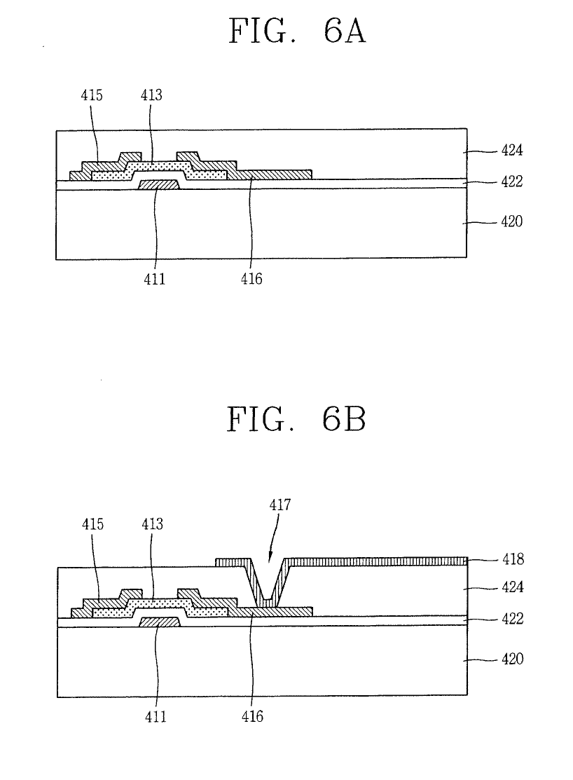

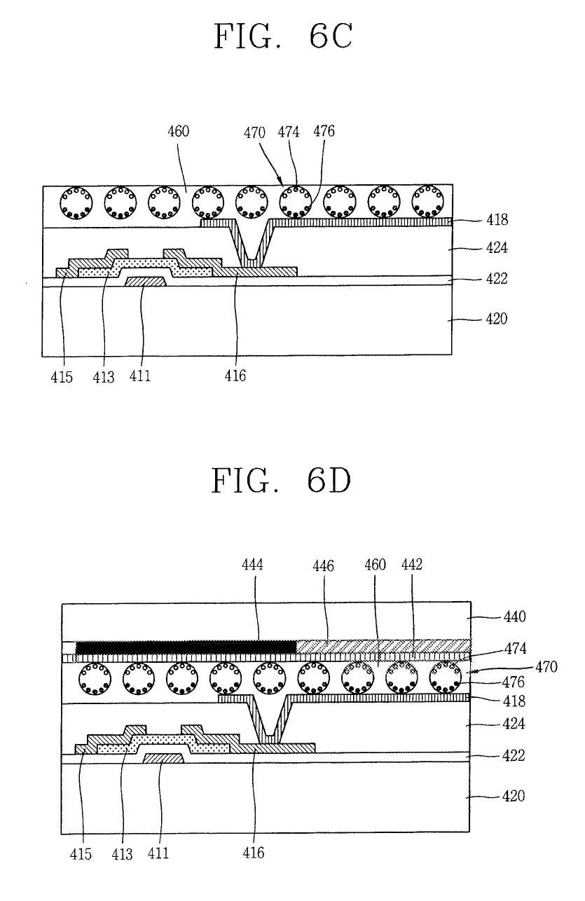

FIGS. 6A to 6D are views sequentially showing a method of fabricating an electrophoretic display device in accordance with a fourth exemplary embodiment. The fourth embodiment exemplarily illustrates that an electrophoretic layer including microcapsules is formed directly on an array substrate.

Referring to FIG. 6A, a TFT comprising a gate electrode 411, a gate insulation layer 422, a semiconductor layer 413, a source electrode 415 and a drain electrode 416 is formed on the first substrate 420, and a passivation layer 424 is formed all over the first substrate 420 to cover the TFT. The TFT may be formed through the processes shown in FIGS. 2A to 2C, and the passivation layer 424 may be formed by depositing an organic insulating material.

Referring to FIG. 6B, the passivation layer 424 is partially etched out to form a contact hole 417. A pixel electrode 418 electrically connected to the drain electrode 416 of the TFT via the contact hole 417 is formed on the passivation layer 424.

Referring to FIG. 6C, an electronic ink material is coated on the first substrate 420 having the pixel electrode 418 to form an electrophoretic layer 460. The electrophoretic layer 460 may be formed by printing microcapsules 470, which electronic inks are filled in polymer binders, on the passivation layer 424 having the pixel electrode 418. Each microcapsule 470 may contain electronic inks, i.e., white particles (or white inks) 474 and black particles (or black inks) 476, and a dispersive medium as a solvent. Here, the white particles 474 and the black particles 476 have positive charge properties and negative charge properties, respectively. That is, the white particles may be charged into positive charge and the black particles 476 may be charged with negative charge.

Referring to FIG. 6D, the first substrate 420 having the electrophoretic layer 460 is bonded to the second substrate 440, thereby fabricating an electrophoretic display device.

A black matrix 444, a color filter layer 446 and a common electrode 442 are formed on the second substrate 440 formed of a transparent material, such as glass or plastic. The black matrix 444 may be formed by depositing and etching an opaque metal, such as Ar, ArOx or the like, or by coating a black resin. The black matrix 444 may be formed on a region on which a real image is not displayed, such as a TFT-formed region, so as to prevent light reflection on the corresponding region.

The color filter layer 446 may include R, G and B sub color filter layers to render actual colors. A white sub pixel, which does not have a color filter layer, may further be provided in each unit pixel for improvement of brightness of the electrophoretic display device. For formation of the white sub pixels, the white sub pixels may be formed in respective unit pixels together with the R, G and B sub pixels. The electrophoretic display device may operate in a reflection mode in which light incident from the exterior is reflected by electrophoretic particles so as to recognize the light. Accordingly, if the color filter layer is further provided on the electrophoretic layer, brightness may be drastically lowered. Hence, in order to solve such problem, the white sub pixels may further be formed in the respective unit pixels so as to improve brightness.

The common electrode 442 may be formed by depositing a transparent conductive material, such as ITO or IZO, on the color filter layer 446. Although not shown, a planarization layer may further be formed on the color filter layer 446. As another method of forming the color filter layer 446, the common electrode 442 may be formed on one surface of the transparent second substrate 440 and the color filter layer 446 may be formed on another surface of the second substrate 440.

After coating a sealant or bonding agent on a non-display region of the thusly-fabricated first or second substrate 420 or 440, the first and second substrates 420 and 440 are bonded in an aligned state, thereby fabricating an electrophoretic display device.

In the electrophoretic display device with the configuration, since the white particles 474 and the black particles 476 contained in the electronic inks dispersed in the microcapsules 470 have positive charge properties and negative charge properties, respectively. Accordingly, when an external signal is applied to the pixel electrode 418 via the TFT formed on the first substrate 420, an electric field is generated between the pixel electrode 418 and the common electrode 442, consequently, the white particles 474 and the black particles 476 are divided within each microcapsule 470 due to the electric field. For instance, when (−) voltage is applied to the pixel electrode 418, the common electrode 442 of the second substrate 440 relatively has (+) potential, such that the white particles 474 with (+) charge move towards the first substrate 420 and the black particles 476 with (−) charge move towards the second substrate 440. Under this state, when light is input from the exterior, i.e., from an upper side of the second substrate 440, the input light is reflected by the black particles 476, thereby rendering a black color.

On the other hand, when (+) voltage is applied to the pixel electrode 418, the common electrode 442 of the second substrate 440 has (−) potential, such that the white particles with (+) charge move towards the second substrate 440 and the black particles 476 with (−) charge move towards the first substrate 420. In this state, when light is input from the exterior, i.e., from an upper side of the second substrate 440, the input light is reflected by the white particles 474. Accordingly, the reflected light can be transmitted through the color filter layer 446 so as to render a color corresponding to the color filter layer 446.

In the drawings, one pixel is shown, but the electrophoretic display device may substantially include pixels with R, G and B color filter layers arranged thereon, accordingly, colors corresponding to the respective pixels can be rendered, thereby enabling desired colors to be displayed.

In the meantime, the electrophoretic display device with the configuration may not be used only as a display device for representing colors. If a color filter layer 446 is not formed on the second substrate 440, light reflected by the white particle 474 may render a white color, while light reflected by the black particle 476 may render a black color. Hence, the electrophoretic display device with the configuration may also be used as a black-and-white display device.

In the electrophoretic display device with the configuration, the white particles 474 and the black particles 476 have positive charge properties and negative charge properties, respectively, however, the polarities of the white and black particles 474 and 476 may be switched for use. That is, the white particles 474 and the black particles 476 may have negative charge properties and positive charge properties, respectively.

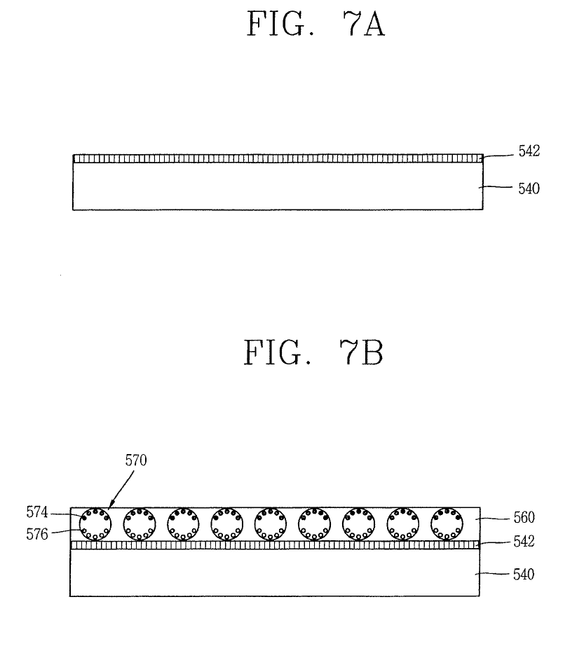

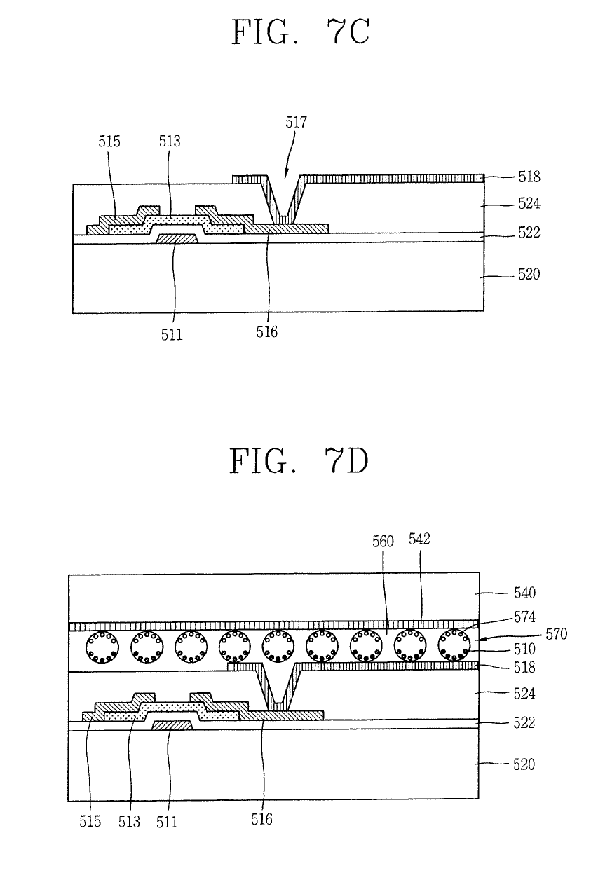

FIGS. 7A to 7D are views sequentially showing a method of fabricating an electrophoretic display device in accordance with a fifth exemplary embodiment. The fifth embodiment exemplarily illustrates that an electrophoretic layer containing microcapsules is formed on an upper substrate having a common electrode.

Referring to FIG. 7A, a transparent conductive material, such as ITO or IZO, is deposited on a second substrate 540 made of a transparent material, such as glass or plastic, to form a common electrode 542. Afterwards, referring to FIG. 7B, an electronic ink material is coated on the second substrate 540 having the common electrode 542, thereby forming an electrophoretic layer 560. The electrophoretic layer 560 may be formed by printing microcapsules 570 filled with electronic inks on the common electrode 542 together with polymer binders, which facilitate coating of the microcapsules 570. The electronic inks dispersed in each microcapsule 470 may contain white particles (or white inks) 574, black particles (or black inks) 576 and a dispersive medium. Here, the white particles 574 and the black particles 576 have positive charge properties and negative charge properties, respectively.

Referring to FIG. 7C, an array substrate is then fabricated. That is, a TFT, which comprises a gate electrode 511, a gate insulation layer 522, a source electrode 515 and a drain electrode 516, is formed on a first substrate 520, and a passivation layer 524 is formed on the TFT. Afterwards, a pixel electrode 518 electrically connected to the drain electrode 516 via a contact hole 517 is formed on the passivation layer 524. Here, the TFT may be formed by the processes shown in FIGS. 2A to 2C.

Referring to FIG. 7D, the first substrate 520 having the TFT is bonded to the second substrate 540 having the electrophoretic layer 560, thereby fabricating an electrophoretic display device.

Although not shown, a color filter layer may be formed on the second substrate 540. The color filter layer may include R, G and B sub color filters within one unit pixel. Light reflected by the electrophoretic layer 560 is transmitted through the color filter layer to render an actual color.

The bonding of the first and second substrates 520 and 540 may be realized by coating a sealant or bonding agent on a non-display region of the first or second substrate 520 or 540 and applying pressure onto the first and second substrates 520 and 540 in an aligned state.

The fourth embodiment exemplarily illustrates that the electrophoretic layer is formed directly on the array substrate having the TFT and thereafter the array substrate is bonded to the upper substrate to fabricate the electrophoretic display device, whereas the fifth embodiment exemplarily illustrates that the electrophoretic layer is formed on the upper substrate having the common electrode and thereafter the upper substrate is bonded to the array substrate to fabricate the electrophoretic display device.

As described so far, since an electrophoretic layer can be formed by being coated directly on a substrate having a TFT or a substrate having a common electrode, an adhesive layer for bonding the electrophoretic layer or a protection film for protecting the adhesive layer may not be needed, as compared to the related art, in which the electrophoretic layer is formed on a independent substrate, thereby reducing a fabricating cost. Also, the electrophoretic layer can be formed through a TFT fabrication line or a common electrode fabrication line, resulting in simplification of a fabrication process.

Also, a protection film for protecting the electrophoretic layer is not used at all, so as to overcome an image quality degradation caused due to static electricity, which is generated upon removing the protection film.

In the meantime, the foregoing description has been given of specific structures of the electrophoretic display device, but it should not be construed that the structure of the electrophoretic display device is merely limited to the specific structures. In particular, various electrophoretic layers, which are currently used, may be applicable as the electrophoretic layer. That is, an electrophoretic layer with any structure, which can be formed on the first substrate, may be applicable.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A method for fabricating an electrophoretic display device comprising:
preparing a first substrate and a second substrate each having a display region and a non-display region;
forming a thin film transistor on the first substrate;
forming a passivation layer on the first substrate having the thin film transistor to be planarized;
forming a pixel electrode on the passivation layer;
forming an electrophoretic layer directly on the passivation layer and the pixel electrode;
forming a common electrode on the second substrate; and
bonding the first substrate and the second substrate to each other.

2. The method of claim 1, wherein the forming of the electrophoretic layer comprises coating an electrophoretic material on the passivation layer and the pixel electrode.

3. The method of claim 2, wherein the electrophoretic material comprises:
microcapsules each containing white particles and black particles, each particle having electric charge, and a dispersing agent for dispersing the white particles and the black particles; and
a solvent for facilitating coating of the microcapsules.

4. The method of claim 2, wherein the electrophoretic material is coated by one of screen printing, roll printing, molding, casting, offset printing and dropping.

5. The method of claim 1, wherein the forming of the electrophoretic layer comprises:
forming partition walls on the passivation layer; and
filling an electrophoretic material in a room defined by the partition walls.

6. The method of claim 1, wherein the forming of the electrophoretic layer comprises:
forming partition walls on the passivation layer;
forming a sealing layer on a room defined by the partition walls, the sealing layer having an injection hole;
injecting an electrophoretic material in the room through the injection hole; and
sealing the injection hole.

7. The method of claim 5 or 6, wherein the forming of the partition walls comprises forming the partition walls on the passivation layer between the pixel electrodes.

8. The method of claim 5 or 6, wherein the forming of the partition walls comprises forming the partition walls overlapping with the passivation layer and the pixel electrode.

9. The method of claim 5 or 6, wherein the electrophoretic material comprises:
white particles and black particles both being charged; and
a dispersing agent for dispersing the white particles and the black particles.

10. The method of claim 5, wherein the forming of the electrophoretic layer further comprises sealing a room defined by the partition walls.

11. The method of claim 3, further comprising forming a color filter layer on the second substrate.

12. The method of claim 1, wherein the forming of the passivation layer comprises forming at least one layer including an organic insulation layer.

13. The method of claim 5, wherein the partition walls are formed through a photolithography process.

14. The method of claim 1, wherein the bonding of the first and second substrates comprises coating a sealant or bonding agent on the non-display region of the first substrate.

15. The method of claim 5, wherein the bonding of the first and second substrates further comprises forming an adhesive layer on the partition walls formed on an edge of the display region and the non-display region.

16. A method for fabricating an electrophoretic display device comprising:
preparing a first substrate and a second substrate each having a display region and a non-display region;
forming a common electrode on the second substrate;
forming an electrophoretic layer directly on the second substrate having the common electrode;
forming a thin film transistor on the first substrate;
forming a passivation layer on the first substrate having the thin film transistor;
forming a pixel electrode on the passivation layer; and
bonding the first substrate and the second substrate to each other.

17. The method of claim 16, wherein the forming of the electrophoretic layer comprises coating an electrophoretic material on the common electrode.

18. The method of claim 17, wherein the electrophoretic material comprises:
white particles and black particles each having electric charge;
microcapsules each containing a dispersing agent for dispersing the white particles and the black particles; and
a solvent for facilitating coating of the microcapsules.

19. The method of claim 17, wherein the electrophoretic material is coated by one of screen printing, roll printing and dropping.

20. The method of claim 16, wherein the forming of the electrophoretic layer comprises:
forming partition walls on the common electrode; and
filling an electrophoretic material in a room defined by the partition walls.

21. An electrophoretic display device comprising:
a first substrate and a second substrate each having a display region and a non-display region;
a thin film transistor formed on the first substrate;
a passivation layer and a pixel electrode formed on the first substrate having the thin film transistor, the pixel electrode formed on the passivation layer;
partition walls formed directly on the passivation layer;
an electrophoretic layer filled in a room defined by the partition walls; and
a common electrode contactable with the partition walls and formed on the second substrate.

22. An electrophoretic display device comprising:
a first substrate and a second substrate each having a display region and a non-display region;
a thin film transistor formed on the first substrate;
a passivation layer and a pixel electrode formed on the first substrate having the thin film transistor, the pixel electrode formed on the passivation layer;
a common electrode formed on the second substrate;
partition walls formed directly on the common electrode and directly contactable with the passivation layer; and
an electrophoretic layer filled in a room defined by the partition walls.

23. The device of claim 21 or 22, further comprising an adhesive layer formed on the non-display region for bonding the first substrate and the second substrate to each other.

24. The device of claim 21, wherein the partition walls are formed on the passivation layer between the pixel electrodes.

25. The device of claim 24, wherein the partition walls are formed on the passivation layer between the pixel electrodes with partially overlapping with the pixel electrodes.

26. The device of claim 24, wherein the partition walls are formed only on the display region of the first substrate.

27. The device of claim 26 or 22, wherein the partition walls are formed such that partition walls formed on an edge of the display region have a wider upper end in width than partition walls formed on other regions of the display region.

28. The device of claim 21 or 22, wherein the electrophoretic layer comprises:
a dispersive medium; and
electronic inks moving within the dispersive medium, the electric ink having electric charge.

29. The device of claim 28, wherein the electronic inks contain white particles and black particles each having electric charge or contain white particles and color particles with specific colors each having electric charge.
